(19) United States
(12) Patent Application Publication
(10) Pub. No.: US 2022/0050141 A1
(43) Pub. Date: Feb. 17, 2022

(54) CONTACT MONITORING UNIT FOR A SAFETY-CRITICAL TRIGGERING APPARATUS OF A SWITCHING DEVICE

(71) Applicant: Siemens Aktiengesellschaft, Muenchen (DE)

(72) Inventors: Juergen RUPP, Muenchen (DE); Martin MAIER, Erbendorf (DE); Uwe WEISS, Amberg (DE)

(73) Assignee: Siemens Aktiengesellschaft, Muenchen (DE)

(21) Appl. No.: 17/274,816

(22) PCT Filed: Sep. 11, 2019
(86) PCT No.: PCT/EP2019/074193

§ 371 Date: Mar. 10, 2021

(30) Foreign Application Priority Data
Sep. 12, 2018 (DE) 10 2018 215 536.4

(51) Int. Cl. G01R 31/327; G01R 31/54; H02H 3/05; H02H 1/00

(52) U.S. Cl. CPC G01R 31/327; H02H 1/0007; H02H 3/05; G01R 31/54

(57) ABSTRACT

A contact monitoring unit is for a safety-critical triggering apparatus of a switching device, including a connection diagram arranged on a first circuit carrier medium for a triggering apparatus and triggering electronics arranged on a second circuit carrier medium. The contact monitoring unit includes redundant electrical connections that are monitored such that, even a failure of a redundant electrical connection is detected.

### PRIORITY STATEMENT

This application is the national phase under 35 U.S.C. § 371 of PCT International Application No. PCT/EP2019/074193 which has an International filing date of Sep. 11, 2019, which designated the United States of America, and which claims priority to German patent application DE 102018215536.4 filed Sep. 12, 2018, the entire contents of each of which are hereby incorporated herein by reference.

### FIELD

Embodiments of the invention generally relate to a contact monitoring unit for a safety-critical tripping apparatus of a switching device with a circuit diagram for a tripping apparatus, the circuit diagram being arranged on a first circuit carrier medium, and tripping electronics arranged on a second circuit carrier medium, and to a method for monitoring this safety-critical tripping apparatus of a switching device.

### BACKGROUND

For safety-critical functions that are triggered by way of an active current signal, it is necessary to ensure that they are not adversely affected by a faulty plug connection, a line break or corrosion. One example of this is the tripping of a switching device by way of a magnetic latch, also referred to as maglatch. If the maglatch and the associated tripping electronics are not accommodated on the same printed circuit board, stringent requirements have to be made of the reliability of the plug or soldered connections since tripping of the switching device by way of the maglatch must be ensured at all events.

### SUMMARY

At least one embodiment of the present invention resides in providing a reliable contact monitoring unit for a safety-critical tripping apparatus of a switching device, and in specifying a method for monitoring this safety-critical tripping apparatus of a switching device.

Embodiments of the the invention include a contact monitoring unit and a method. The claims relate to advantageous embodiments and developments, which can be used individually or in combination with one another.

According to an embodiment of the invention, a contact monitoring unit, for a safety-critical tripping apparatus of a switching device including a tripping apparatus arranged on a first circuit carrier medium and tripping electronics arranged on a second circuit carrier medium, comprises redundant electrical connections that are monitored in such a way that even the failure of a redundant electrical connection is to be recognized.

Another embodiment of the invention is directed to a method for monitoring a safety-critical tripping apparatus of a switching device with a circuit diagram for a tripping apparatus, the circuit diagram being arranged on a first circuit carrier medium, and tripping electronics arranged on a second circuit carrier medium, wherein the total impedance in the electrical circuit constituted from the circuit diagram for the tripping apparatus and the circuit diagram of the tripping electronics, which are connected to one another via redundant electrical connections, is determined and is fed to a comparator or to an analog-to-digital converter (ADC) for evaluation.

### BRIEF DESCRIPTION OF THE DRAWINGS

Further advantages and embodiments of the invention are explained in greater detail below on the basis of an example embodiment and with reference to the drawing.

In the figures here:

FIG. 1 shows a circuit diagram of a contact monitoring unit according to an embodiment of the invention for a safety-critical tripping apparatus of a switching device;

FIG. 2 shows a diagram of a current profile during a simulation with and without a line defect of a redundant electrical connection;

FIG. 3 shows a circuit diagram of a contact monitoring unit according to an embodiment of the invention for a safety-critical tripping apparatus of a switching device with individual driving.

### LIST OF REFERENCE SIGNS

1 Circuit carrier medium
2 Circuit carrier medium
3 Redundant electrical connections
4 Tripping electronics
5 Tripping apparatus
6 Transistor
7 Series resistor
8 Capacitance
9 Shunt
10 Curve profile
11 Curve profile
12 Circuit carrier medium
13 Circuit carrier medium
14 Redundant electrical connections
15 Tripping electronics
16 Tripping apparatus
17 Transistor
18 Shunt

### DETAILED DESCRIPTION OF EMBODIMENTS OF THE INVENTION

According to an embodiment of the invention, a contact monitoring unit, for a safety-critical tripping apparatus of a switching device including a tripping apparatus arranged on a first circuit carrier medium and tripping electronics arranged on a second circuit carrier medium, comprises redundant electrical connections that are monitored in such a way that even the failure of a redundant electrical connection is to be recognized.

An embodiment of the invention is based on a redundant embodiment of the electrical connections. In this case, the connection is monitored such that even the failure of a redundant connection is recognized. Thus, either a warning that the device must be exchanged can be output, or tripping can be carried out immediately by way of the remaining redundant connection.

An embodiment of the invention includes monitoring of the redundant connections with the possibility of recognizing the failure of an individual connection.

For the contact monitoring unit according to an embodiment of the invention, provision is made for the tripping electronics and the magnetic release, e.g. a maglatch, not to be arranged on one structural unit, i.e. printed circuit board or circuit carrier medium, but rather to be coupled via a cable/plug/soldered connection. In order to trip the switching device, a transistor is driven so that a current flows through the magnetic release and unlatches the latter. Once this connection has been interrupted, the switching device can no longer trip, as a result of which a safety-critical state is triggered.

In order to increase safety, the connection between the circuit carrier media can be established in a redundant fashion by using a plurality of cables via a plurality of plug contacts/soldered connections for the connection. The failure of an individual cable/contact then still does not adversely affect the function. The connection must nevertheless be monitored since otherwise the individual failure may remain unnoticed for a long time and ultimately leads to the breakdown of the device as a result of the failure of a further connection.

According to an embodiment of the invention, a transistor that normally drives the current for tripping the magnetic release is driven only with a short pulse that is not sufficient to trigger the unlatching of the magnetic release. The short pulse is however sufficient to lead to a current flow, the profile of which is dependent on the total impedance of the electrical circuit. The total impedance is formed by series resistors together with the inductance and the resistance of the magnetic release. If a plug connection or a cable then fails, the total impedance will increase and the current becomes somewhat smaller. The current is measured and fed for example to a comparator or to an analog-to-digital converter (ADC) for evaluation.

If the lines themselves already have an impedance sufficient to detect the failure, the series resistors can also be omitted.

In order that even a very short pulse is sufficient to obtain an evaluatable current, a capacitance can also be connected in parallel with the magnetic release. The current will then rise rapidly, but flow almost exclusively through the capacitance and not trip the magnetic release.

With a longer pulse, however, the impedance of the magnetic release itself can also be monitored.

The behavior described can be observed in the simulation. The changed behavior can be registered given a suitable choice of a comparator threshold. Many microcontrollers contain such a comparator, and so no additional outlay arises apart from the series resistors. Even the latter can be dispensed with if the impedance of the electrical connections is large enough.

It should also be taken into consideration that the line resistances and the inductance of the magnetic release exhibit tolerances to a high degree, such that the difference between the normal range and the tripping threshold is too small to stipulate a predefined tripping threshold. It may therefore be expedient to ascertain the normal range at the beginning by way of a teach-in function, e.g. by way of an ADC.

In one particularly advantageous configuration of the contact monitoring unit according to an embodiment of the invention, it can be provided that in the event of failure of a redundant electrical connection, a warning is output or tripping of the tripping apparatus is carried out promptly by way of the remaining redundant electrical connections.

A continuation of this concept according to an embodiment of the invention can reside in the fact that the tripping electronics on the second circuit carrier medium comprise at least one transistor which is drivable by way of a short electrical pulse which is not sufficient to implement the unlatching of the tripping apparatus.

As a continuation of this concept, one specific embodiment reveals that the tripping electronics on the second circuit carrier medium comprise a plurality of series resistors that are electrically connected to the transistor.

In one particularly advantageous configuration of the contact monitoring unit according to an embodiment of the invention, it can be provided that the total impedance of the tripping electronics is formed by the inductance, the resistance in the tripping apparatus and the plurality of series resistors.

One continuation of this concept according to an embodiment of the invention can reside in the fact that the failure of a redundant electrical connection is identified by an increase in the total impedance or a reduction of current flow.

As a continuation of this concept, one specific embodiment reveals that in the event of failure of a redundant electrical connection, the current flow is measured and is fed to a comparator or to an analog-to-digital converter (ADC) for evaluation.

In one particularly advantageous configuration of the contact monitoring unit according to an embodiment of the invention, it can be provided that the plurality of series resistors are to be replaced by a suitable line in the case of sufficient impedance.

One continuation of this concept according to an embodiment of the invention can reside in the fact that a capacitance is connected in parallel with the tripping apparatus on the first circuit carrier medium, such that even a short electrical pulse is sufficient to obtain an evaluatable current.

As a continuation of this concept, one specific embodiment reveals that the redundant electrical connections are to be driven individually.

In one particularly advantageous configuration of the contact monitoring unit according to an embodiment of the invention, it can be provided that for the case where the line resistances and the resistance in the tripping apparatus have a tolerance range, a teach-in function is embodied in the contact monitoring unit.

Another embodiment of the invention is directed to a method for monitoring a safety-critical tripping apparatus of a switching device with a circuit diagram for a tripping apparatus, the circuit diagram being arranged on a first circuit carrier medium, and tripping electronics arranged on a second circuit carrier medium, wherein the total impedance in the electrical circuit constituted from the circuit diagram for the tripping apparatus and the circuit diagram of the tripping electronics, which are connected to one another via redundant electrical connections, is determined and is fed to a comparator or to an analog-to-digital converter (ADC) for evaluation.

As a continuation of this method, one specific embodiment reveals that in the event of failure of a redundant electrical connection, a warning is output or tripping of the tripping apparatus is carried out promptly by way of the remaining redundant electrical connections.

The contact monitoring unit according to an embodiment of the invention for a safety-critical tripping apparatus of a switching device comprises two circuit carrier media, which are connected to one another via redundant electrical connections. The tripping electronics of a magnetic tripping apparatus are arranged on the first circuit carrier medium. The tripping apparatus is arranged on the second circuit carrier medium. The tripping electronics comprise a transistor that is electrically connected to a plurality of series resistors. The plurality of series resistors are connected to the tripping apparatus via the electrically redundant connections. A capacitance can be connected in parallel with the tripping apparatus on the circuit carrier medium. In addition, a shunt can be positioned upstream of the transistor.

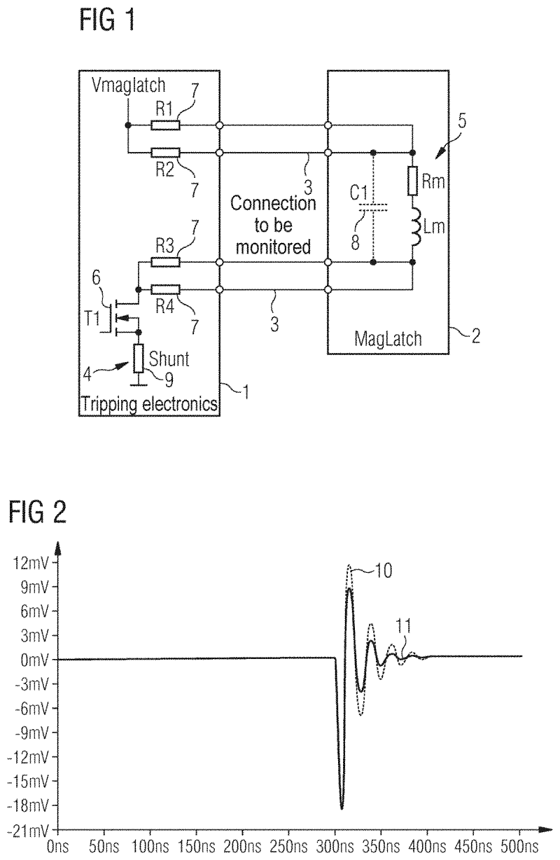

FIG. 1 shows a contact monitoring unit according to an embodiment of the invention for a safety-critical tripping apparatus of a switching device. This contact monitoring unit comprises two circuit carrier media 1, 2, which are connected to one another via redundant electrical connections 3. The tripping electronics 4 of a magnetic tripping apparatus 5 are arranged on the circuit carrier medium 1. The tripping apparatus 5 is arranged on the second circuit carrier medium. The tripping electronics 4 comprise a transistor 6 that is electrically connected to a plurality of series resistors 7. The plurality of series resistors 7 are connected to the tripping apparatus 5 via the electrically redundant connections 3. A capacitance 8 can be connected in parallel with the tripping apparatus 5 on the circuit carrier medium 2. In addition, a shunt 9 can be positioned upstream of the transistor 6.

FIG. 2 shows a current profile during a simulation with and without a line defect of a redundant electrical connection. The curve profile 10 shows the current profile of an intact redundant electrical connection 3. The curve profile 11 shows the current profile of a defective redundant electrical connection 3. The changed behavior can be registered given a suitable choice of a comparator threshold. Many microcontrollers contain such a comparator, and so no additional outlay arises apart from the series resistors. Even the latter can be dispensed with if the impedance of the electrical connections is large enough.

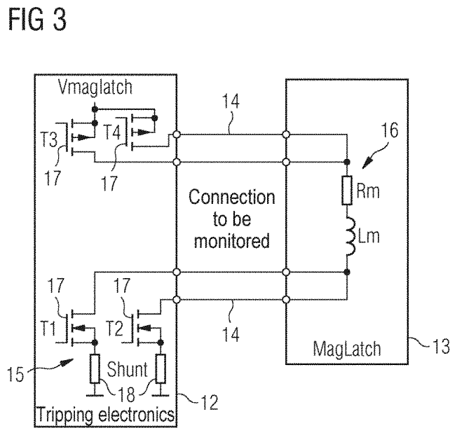

FIG. 3 shows a contact monitoring unit according to an embodiment of the invention for a safety-critical tripping apparatus of a switching device with individual driving. The contact monitoring unit comprises two circuit carrier media 12, 13, which are connected to one another via redundant electrical connections 14. The tripping electronics 15 of a magnetic tripping apparatus 16 are arranged on the circuit carrier medium 12. The tripping apparatus 16 is arranged on the second circuit carrier medium 13. The tripping electronics 15 comprise a plurality of transistors 17 that are individually electrically connected to the tripping apparatus 16 via the redundant electrical connections 14. Shunts 18 can be positioned upstream of the transistors 17.

The contact monitoring unit according to an embodiment of the invention and the method for monitoring a safety-critical tripping apparatus of a switching device are distinguished by the fact that by way of the monitoring of the redundant connections, the failure of individual redundant connections can be recognized reliably and simply by measurement of the total impedance.

1. A contact monitoring unit for a safety-critical tripping apparatus of a switching device including a circuit diagram for a tripping apparatus, the circuit diagram being arranged on a first circuit carrier medium, and tripping electronics arranged on a second circuit carrier medium, the contact monitoring unit comprising:
redundant electrical connections, configured to be monitored such that even a failure of a redundant electrical connection, of the redundant electrical connections, is recognized.

2. The contact monitoring unit of claim 1, wherein, upon recognizing the failure of the redundant electrical connection, of the redundant electrical connections, a warning is output or tripping of the tripping apparatus is carried out, via remaining redundant electrical connections of the redundant electrical connections.

3. The contact monitoring unit of claim 1, wherein the tripping electronics on the second circuit carrier medium at least one transistor, is drivable by way of a short electrical pulse, insufficient to implement unlatching of the tripping apparatus.

4. The contact monitoring unit of claim 1, wherein the tripping electronics on the second circuit carrier medium include a plurality of series resistors, electrically connected to the transistor.

5. The contact monitoring unit of claim 1, wherein a impedance of the tripping electronics is formed by inductance, resistance in the tripping apparatus the plurality of series resistors.

6. The contact monitoring unit of claim 1, wherein the failure of theredundant electrical connection of the redundant electrical connections, is recognized by an increase in total impedance or a reduction of current flow.

7. The contact monitoring unit of claim 1, wherein, upon recognizing the failure of the redundant electrical connection, of the redudant electrical connections, current flow is measured and measurement of the current flow is fed to a comparator or to an analog-to-digital converter for evaluation.

8. The contact monitoring unit of claim 4, wherein the plurality of series resistors are replaceable by a suitable line in the case of sufficient impedance.

9. The contact monitoring unit of claim 1, wherein a capacitance is connected in parallel with the tripping apparatus on the first circuit carrier medium, such that even a short electrical pulse is sufficient to obtain an evaluatable current.

10. The contact monitoring unit of claim 1, wherein the redundant electrical connections are individually drivable.

11. The contact monitoring unit of claim 1, wherein, the line resistances and the resistance in the tripping apparatus having a tolerance range, a teach-in function is embodied in the contact monitoring unit.

12. A method for monitoring a safety-critical tripping apparatus of a switching device with a circuit diagram for a tripping apparatus, the circuit diagram being arranged on a first circuit carrier medium, and tripping electronics being arranged on a second circuit carrier medium, that the method comprising:
determining a total impedance, in an electrical circuit constituted from the circuit diagram for the tripping apparatus and the circuit diagram of the tripping electronics, connected to one another via redundant electrical connections; and
feeding the total impedance determined to a comparator or to an analog-to-digital converter for evaluation.

13. The method of claim 12, further comprising:
outputting a warning or carrying out a tripping of the tripping apparatus, uupon recognizing failure of a redundant electrical connection, of the redundant electrical connections, via remaining redundant electrical connections of the redundant electrical connections.

14. The contact monitoring unit of claim 2, wherein the tripping electronics on the second circuit carrier medium include at least one transistor, drivable by way of a short electrical pulse, insufficient to implement unlatching of the tripping apparatus.

15. The contact monitoring unit of claim 2, wherein the tripping electronics on the second circuit carrier medium include a plurality of series resistors, electrically connected to the transistor.

16. The contact monitoring unit of claim 2, wherein a total impedance of the tripping electronics is formed by inductance, resistance in the tripping apparatus and the plurality of series resistors.

17. The contact monitoring unit of claim 2, wherein the failure of the redundant electrical connection of the redundant electrical connections, is recognized by an increase in total impedance or a reduction of current flow.

18. The contact monitoring unit of claim 2, wherein a capacitance is connected in parallel with the tripping apparatus on the first circuit carrier medium, such that even a short electrical pulse is sufficient to obtain an evaluatable current.

19. The contact monitoring unit of claim 2, wherein the redundant electrical connections are individually drivable.

20. The method claim 12, the method further comprising:
measuring current flow, upon recognizing the failure of the redundant electrical connection, of the redundant electrical connections; and
feeding a current flow measurement determined from the measuring, to a comparator or to an analog-to-digital converter for evaluation.
